(19) United States
(12) Patent Application Publication
(10) Pub. No.: US 2017/0022358 A1
(43) Pub. Date: Jan. 26, 2017

(54) THERMOPLASTIC COMPOSITION

(71) Applicant: MITSUBISHI CHEMICAL EUROPE GMBH, Düsseldorf (DE)

(72) Inventor: Bernardus Antonius Gerardus SCHRAUWEN, Leende (NL)

(73) Assignee: MITSUBISHI CHEMICAL EUROPE GMBH, Düsseldorf (DE)

(21) Appl. No.: 15/300,942

(22) PCT Filed: Apr. 3, 2015
(86) PCT No.: PCT/EP2015/097014

§ 371 Date: Sep. 30, 2016

(30) Foreign Application Priority Data
Apr. 7, 2014 (EP) 14163753.8

(51) Int. Cl. C08L 69/00; C23C 18/20; H01Q 1/38; H05K 3/00; H05K 3/18; C08J 7/12; C23C 18/16

(52) U.S. Cl. CPC C08L 69/00; C08J 7/123; C23C 18/204; C23C 18/1608; C23C 18/1612; C23C 18/1641; H05K 3/0014; H05K 3/185; H01Q 1/38; C08L 2203/20; C08L 2205/06; C08J 2369/00; C08J 2413/00; H05K 2203/107

(57) ABSTRACT

A thermoplastic composition including:
a) 30-97 wt % of an aromatic polycarbonate;
b) 0.5-25 wt % of a laser direct structuring additive; and
c) 2-15 wt % of a methylmethacrylate butadiene styrene based rubber;
d) 0.1-15 wt % of one or more conductive track adhesion agents selected from the group consisting of an organic phosphate, a phosphazene compound and a hypophosphorous acid metal salt, wherein a molded part of the composition provided with a conductive track made by a laser radiation and a subsequent metallization has a classification 0 as determined according to ISO2409:2013 after being subjected to conditions of 65° C. and 85% Relative Humidity for 24 hours.

### FIELD OF THE INVENTION

The present invention relates to a thermoplastic composition comprising a thermoplastic resin and a laser direct structuring additive. The invention also relates to a molded part comprising the composition and the molded part provided with a conductive track by a laser radiation and a subsequent metallization.

### BACKGROUND OF THE INVENTION

Polymer compositions comprising a polymer and a laser direct structuring (LDS) additive are for example described in U.S. Pat. No. 7,060,421 and WO-A-2009024496. Such polymer compositions can advantageously be used in an LDS process for producing a non-conductive part on which conductive tracks are to be formed by irradiating areas of said part with laser radiation to activate the plastic surface at locations where the conductive path is to be situated and subsequently metalizing the irradiated areas to accumulate metal on these areas. WO-A-2009024496 describes aromatic polycarbonate compositions containing a metal compound capable of being activated by electromagnetic radiation and thereby forming elemental metal nuclei and 2.5-50 wt % of a rubber like polymer, the latter being added to reduce degradation of the polycarbonate due to the presence of such metal compound in aromatic polycarbonate compositions. Examples of the rubber-like polymer mentioned include acrylonitrile butadiene styrene rubber (ABS), methylmethacrylate butadiene styrene rubber (MBS) and siloxane based rubber.

Important properties of aromatic polycarbonate compositions comprising rubber-like polymers include flame retardancy and Vicat hardness. Further, for articles with conductive tracks provided by laser radiation and subsequent metallization, it is important that the conductive tracks do not delaminate. The delamination was found to be a problem especially in high humidity, high temperature conditions.

WO2012056416 discloses a thermoplastic composition for use in an LDS process. WO2012056416 mentions an article of manufacture having a metal layer provided by an LDS process, wherein the metal layer has a peel strength of 0.3 N/mm or higher as measured according to IPC-TM-650. WO2012056416 does not mention an article having a good delamination property in combination with a high Vicat temperature and flame retardancy.

### SUMMARY OF THE INVENTION

It is an object of the invention to provide a polymer composition which can produce a molded article with conductive tracks which is less susceptible to delamination suitable for applications requiring high Vicat temperature and flame retardancy.

### DETAILED DESCRIPTION OF THE INVENTION

Accordingly, the present invention provides a thermoplastic composition comprising:
a) 30-97 wt %, preferably 50-97 wt %, of an aromatic polycarbonate;
b) 0.5-25 wt % of a laser direct structuring additive; and
c) 2-15 wt % of a methylmethacrylate butadiene styrene based rubber having a butadiene content of at least 50 wt %;
d) 0.1-15 wt % of one or more conductive track adhesion agents selected from the group consisting of an organic phosphate, a phosphazene compound and a hypophosphorous acid metal salt,

wherein a molded part of the composition provided with a conductive track made by a laser radiation and a subsequent metallization has a classification 0 as determined according to ISO2409:2013 after being subjected to conditions of 65° C. and 85% Relative Humidity for 24 hours.

It has surprisingly been found that the combination of the specific MBS and component d) in an aromatic polycarbonate (herein sometimes referred as PC) composition comprising a laser direct structuring additive (herein sometimes referred as LDS additive) leads to the combination of good flame retardancy, good Vicat temperature and good delamination resistance.

The conductive tracks provided by an LDS process, i.e. laser radiation and subsequent metallization are susceptible to delamination when the conductive tracks are formed on articles made from a PC composition comprising LDS additive without rubber.

It was surprisingly found that component d) acts as a conductive track adhesion agent, i.e. it reduces the possibility of delamination of the conductive tracks from the surface of the molded part in combination with the MBS used in the composition of the invention. Although not wishing to be bound by any theory, the inventors believe that this is caused by component d) reducing the possibility of the degradation of PC. The delamination problem is believed to be caused by the fact that some amounts of alkaline compound used during the chemical plating remain between the surface of the molded part and the conductive tracks. This remaining alkaline compound degrades PC forming the molded part, which leads to delamination of the conductive tracks from the molded part. By preventing the degradation of PC, the delamination of the conductive tracks is prevented. Component d) is believed to reduce the degradation of PC in combination with the MBS specified above.

The delamination problem can also be solved by the addition of ABS rubber to a PC composition. However, PC/ABS composition has the problem that it requires a high amount of flame retardants for achieving high flame retardancy. High amount of flame retardants results in a low Vicat temperature. A PC/ABS composition added with a flame retardant of an organic phosphate, a phosphazene compound or a hypophosphorous acid metal salt either has a low flame retardancy or a low Vicat temperature. Hence, PC/ABS composition cannot achieve the combination of good flame retardancy, good Vicat temperature and good delamination resistance. An alternative solution to the delamination problem is the use of polyester. However, PC/polyester composition has a similar problem as PC/ABS composition in that it cannot achieve the combination of good flame retardancy and good Vicat temperature.

Component d) has a further function as a flame retardant. PC/MBS composition does not require a high amount of component d) or further flame retardants for achieving good flame retardancy. Hence, PC/MBS composition gives a combination of good flame retardancy, good Vicat temperature and good delamination resistance by the addition of component d). The effect of component d) was not observed with a PC/Si-based rubber composition.

The composition according to the invention can be formed into a molded part and a conductive track can be provided thereon by a laser radiation and a subsequent metallization step. The molded part with the conductive track according to the invention has a classification 0 as determined according to ISO2409:2013 after being subjected to conditions of a temperature of 65° C. and a relative humidity of 85% for a period of 24 hours.

Preferably, the molded part with the conductive track according to the invention has a classification 0 as determined according to ISO2409:2013 after being subjected to conditions of a temperature of 75° C. and a relative humidity of 85% for a period of 24 hours. Preferably, the molded part with the conductive track according to the invention has a classification 0 as determined according to ISO2409:2013 after being subjected to conditions of a temperature of 85° C. and a relative humidity of 85% for a period of 24 hours. Preferably, the molded part with the conductive track according to the invention has a classification 0 as determined according to ISO2409:2013 after being subjected to conditions of a temperature of 65° C. and a relative humidity of 85% for a period of 48 hours. Preferably, the molded part with the conductive track according to the invention has a classification 0 as determined according to ISO2409:2013 after being subjected to conditions of a temperature of 75° C. and a relative humidity of 85% for a period of 48 hours. Preferably, the molded part with the conductive track according to the invention has a classification 0 as determined according to ISO2409:2013 after being subjected to conditions of a temperature of 85° C. and a relative humidity of 85% for a period of 48 hours.

The invention further relates to a molded part comprising the thermoplastic composition according to the present invention. The invention relates in particular to a molded part produced by injection moulding of the composition according to the invention. The invention further also relates to an article, in particular a circuit carrier, that contains a molded part produced from the composition according to the invention and a conductive track provided thereon. In one embodiment, such a circuit carrier is used for producing an antenna.

The invention further relates to a process for producing such a circuit carrier which process comprises the steps of providing a molded part comprising the thermoplastic composition according to the present invention, irradiating areas of said part on which conductive tracks are to be formed with laser radiation, and subsequently metallizing the irradiated areas. In a preferred embodiment, the laser irradiation is used to simultaneously release metal nuclei and effect ablation of the part while forming an adhesion-promoting surface. This provides a simple means to achieve excellent adhesive strength of the deposited metallic conductor tracks. The wavelength of the laser is advantageously 248 nm, 308 nm, 355 nm, 532 nm, 1064 nm or of even 10600 nm. The deposition of further metal onto the metal nuclei generated by laser radiation preferably takes place via plating processes. Said metallization is preferably performed by immersing the molded part in at least one electroless plating bath to form electrically conductive pathways on the irradiated areas of the molded part. Non-limiting examples of electroless plating processes are a copper plating process, gold plating process, nickel plating process, silver plating, zinc plating and tin plating. Preferably, the first plating is copper plating. The conductive track may have one or more layers. The first layer may e.g. be a copper layer and may be 8-16 μm, more typically 8-12 μm. If present, the second layer may e.g. be a nickel layer and may be 2-4 μm. If present, the third layer may be e.g. be a gold layer and may be 0.05-0.2 μm.

The irradiation of the molded part may e.g. be performed under conditions comprising a power of 2-15 W, a frequency of 20-100 kHz, a speed of 1-5 m/s.

The irradiation of the molded part may e.g. be performed by UV light having a wavelength from 100 to 400 nm, visible light having a wavelength from 400 to 800 nm, or infrared light having a wavelength from 800 to 25 000 nm. Other preferred forms of radiation are X-rays, gamma rays, and particle beams (electron beams, α-particle beams, and β-particle beams).

When the irradiation of the molded part is performed by UV light having a wavelength from 100 to 400 nm, it may be preferable that the molded part with the metallized areas is subjected to thermal processing for improving the delamination resistance. The thermal processing may be performed by subjecting the molded part to microwave e.g. by placing the molded part in a microwave oven. Preferably, the irradiation of the molded part is performed by visible light having a wavelength from 400 to 800 nm, or infrared light having a wavelength from 800 to 25 000 nm, or X-rays, gamma rays or particle beams. These types of laser radiation are advantageous in that the metal layer on the irradiated areas has a relatively stronger adhesion strength without requiring thermal processing after the plating step.

More preferably, the irradiation of the molded part is performed by visible light having a wavelength from 400 to 800 nm, or infrared light having a wavelength from 800 to 25 000 nm. Most preferably, the irradiation of the molded part is performed by infrared light having a wavelength from 800 to 25 000 nm.

Preferably, the process for producing the circuit carrier does not comprise a step of thermal processing after the step of metallizing the irradiated areas. This is advantageous in view of allowing an efficient process.

Preferably, a molded part of the composition according to the invention, optionally provided with a conductive track made by a laser radiation and a subsequent metallization, is capable of achieving UL94 V0 rating at a thickness of 3.2 mm (±10%) and more preferably capable of achieving UL94 V0 rating at a thickness of 1.6 mm (±10%).

Preferably, the Vicat B50 (Vicat Softening Temperature measured according to ISO 306 with a load of 50 N at a rate of 50° C./hour) of a molded part of the composition, optionally provided with a conductive track made by a laser radiation and a subsequent metallization, is higher than 100° C., more preferably 110° C., even more preferably 120° C.

Preferably, a molded part of the composition according to the invention provided with a conductive track made by a laser radiation and a subsequent metallization step
has a classification 0 as determined according to ISO2409:2013 after being subjected to conditions of a temperature of 65° C. and a relative humidity of 85% for a period of 24 hours;
is capable of achieving UL94 V0 rating at a thickness of 3.2 mm (±10%) and
has a Vicat B50 of higher than 100° C.

Preferably, the Izod Notched impact strength at 23° C. (measured at a sample thickness of 3.2 mm or less according to ISO 180/4A) of a molded part of the composition, optionally provided with a conductive track made by a laser radiation and a subsequent metallization, is a value higher than 20 kJ/m², even higher than 30 kJ/m², even higher than 40 kJ/m², even higher than 50 kJ/m², and even higher than 60 kJ/m².

The present invention further provides use of an organic phosphate, a phosphazene compound and/or a hypophosphorous acid metal salt in a composition comprising an aromatic polycarbonate, a methylmethacrylate butadiene styrene based rubber and a laser direct structuring additive for improving the adhesion of a conductive track to a molded part of said composition, wherein the conductive track has been provided on the molded part by a laser radiation and a subsequent metallization.

The use may be for improving the adhesion after being subjected to conditions of 65° C. and 85% Relative Humidity for 24 hours. The use may be for the molded part of the composition provided with the conductive track to achieve a classification 0 as determined according to ISO2409:2013 after being subjected to conditions of 65° C. and 85% Relative Humidity for 24 hours.

A further aspect of the present invention relates to a process for improving the adhesion of a conductive track to a molded part of the composition comprising an aromatic polycarbonate, a methylmethacrylate butadiene styrene based rubber and a laser direct structuring additive, wherein the conductive track has been provided on the molded part by a laser radiation and a subsequent metallization, wherein the process comprises incorporating into the composition an effective amount of an organic phosphate, a phosphazene compound and/or a hypophosphorous acid metal salt prior to the laser radiation.

A further aspect of the present invention relates to the thermoplastic composition according to the invention for use in a laser direct structuring process.

A further aspect of the present invention relates to use of the thermoplastic composition according to the invention in a laser direct structuring process.

Component d)

The amount of component d) is 0.1-15 wt %, preferably 2-10 wt %, more preferably 3-9 wt % with respect to the weight of the total composition.

Preferably, component d) is an organic phosphate or a phosphazene compound. Most preferably, component d) is a phosphazene compound.

Organic Phosphate

An example of the organic phosphate is an aromatic phosphate of the formula (GO)₃P═O, wherein each G is independently an alkyl, cycloalkyl, aryl, alkaryl, or aralkyl group, provided that at least one G is an aromatic group. Two of the G groups may be joined together to provide a cyclic group, for example, diphenyl pentaerythritol diphosphate, which is described by Axelrod in U.S. Pat. No. 4,154,775. Other suitable aromatic phosphates may be, for example, phenyl bis(dodecyl) phosphate, phenyl bis(neopentyl) phosphate, phenyl bis(3,5,5′-trimethylhexyl) phosphate, ethyl diphenyl phosphate, 2-ethylhexyl di(p-tolyl) phosphate, bis(2-ethylhexyl) p-tolyl phosphate, tritolyl phosphate, bis(2-ethylhexyl) phenyl phosphate, tri(nonylphenyl) phosphate, bis(dodecyl) p-tolyl phosphate, dibutyl phenyl phosphate, 2-chloroethyl diphenyl phosphate, p-tolyl bis(2,5,5′-trimethylhexyl) phosphate, 2-ethylhexyl diphenyl phosphate, or the like. A specific aromatic phosphate is one in which each G is aromatic, for example, triphenyl phosphate, tricresyl phosphate, isopropylated triphenyl phosphate, and the like. Di- or polyfunctional aromatic phosphorus-containing compounds are also useful, for example, compounds of the formulas below:

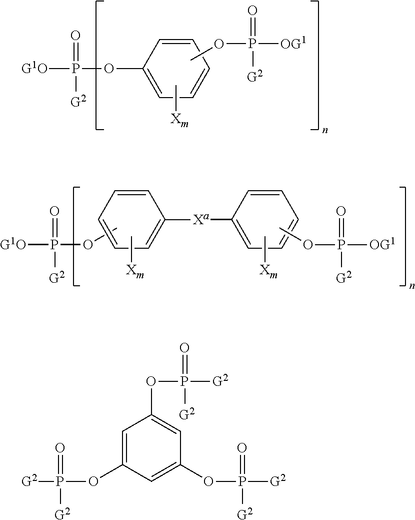

wherein each G¹ is independently a hydrocarbon having 1 to 30 carbon atoms; each G² is independently a hydrocarbon or hydrocarbonoxy having 1 to 30 carbon atoms; each X is independently a bromine or chlorine; m 0 to 4, and n is 1 to 30.

Examples of suitable di- or polyfunctional aromatic phosphorus-containing compounds include resorcinol tetraphenyl diphosphate (RDP), the bis(diphenyl) phosphate of hydroquinone and the bis(diphenyl) phosphate of bisphenol-A, respectively, their oligomeric and polymeric counterparts, and the like. Methods for the preparation of the aforementioned di- or polyfunctional aromatic compounds are described in British Patent No. 2,043,083.

Phosphazene Compound

A phosphazene compound is an organic compound containing —P═N bond. Particularly preferred phosphazene compounds include phenoxyphosphazene oligomer (also known as poly(bis(phenoxy)phosphazene)). An example of the phenoxyphosphazene oligomer is FP-110 ® from Fushimi Pharmaceutical Co., Ltd.

Other preferred phosphazene compounds that are commercially available include SPB-100 ® from Otsuka Chemical Co., Ltd., LY202 ® from Lanyin Chemical Co., Ltd.

Hypophosphorous Acid Metal Salt

Preferred examples of component d) include hypophosphorous acid metal salts as described in WO2005/044906.

The “metal” which acts as a counter ion in the hypophosphorous acid metal salts is an alkaline metal belonging to the first, second and third main group or second, seventh, eighth subgroup of the periodic table of the elements. Preferably, the metal is selected from the group consisting of: Ca, Ba, Mg, Al, Zn, Fe and B.

Particularly preferred hypophosphorous acid metal salts are calcium hypophosphite and aluminum hypophosphite, calcium hypophosphite being the most preferred.

In particularly preferred embodiments, component d) is the combination of the hypophosphorous acid metal and an organic phosphate as described above. More preferably, component d) is the combination of the hypophosphorous acid metal and an organic phosphoric ester such as triphenylphosphate (TPP), tricresyl phosphate, trixylilenphosphate, resorcinoldiphosphate, resorcinolbis diphenylphosphate, bisphenol A bis diphosphate, trimethylphosphate, tributylphosphate, trioctylphosphate or similar products. The preferred ratio of the hypophosphorous acid metal and the organic phosphate is 2:1 to 5:1.

Particularly preferred as component d) includes a mixture of calcium hypophosphite and resorcinol tetraphenyl diphosphate. An example of this mixture is commercially available as Phoslite B85CX from Italmatch Chemicals (Italy).

Component a)

The concentration of a) aromatic polycarbonate in the composition of the present invention is at least 30 wt %, for example at least 40 wt %, for example at least 45 wt %. Preferably, the concentration of a) aromatic polycarbonate in the composition of the present invention is between 50 wt % and 97 wt %, more preferably between 55 wt % and 95 wt %, even more preferably from 60 up to 85 mass %, with respect to the weight of the total composition.

Polycarbonates including aromatic carbonate chain units include compositions having structural units of the formula (I):

—R¹—O—CO—O— (I)

in which the R¹ groups are aromatic, aliphatic or alicyclic radicals. Beneficially, R¹ is an aromatic organic radical and, in an alternative embodiment, a radical of the formula (II):

-A¹-Y¹-A²- (II)

wherein each of A¹ and A² is a monocyclic divalent aryl radical and Y¹ is a bridging radical having zero, one, or two atoms which separate A¹ from A². In an exemplary embodiment, one atom separates A¹ from A². Illustrative examples of radicals of this type are —O—, —S—, —S(O)—, —S(O2)-, —C(O)—, methylene, cyclohexyl-methylene, 2-[2,2,1]-bicycloheptylidene, ethylidene, isopropylidene, neopentylidene, cyclohexylidene, cyclopentadecylidene, cyclododecylidene, adamantylidene, or the like. In another embodiment, zero atoms separate A¹ from A², with an illustrative example being bisphenol. The bridging radical Y¹ can be a hydrocarbon group or a saturated hydrocarbon group such as methylene, cyclohexylidene or isopropylidene.

Suitable aromatic polycarbonates include polycarbonates made from at least a divalent phenol and a carbonate precursor, for example by means of the commonly known interfacial polymerization process or the melt polymersiation method. Suitable divalent phenols that may be applied are compounds having one or more aromatic rings that contain two hydroxy groups, each of which is directly linked to a carbon atom forming part of an aromatic ring. Examples of such compounds are:

4,4′-dihydroxybiphenyl, 2,2-bis(4-hydroxyphenyl)propane (bisphenol A), 2,2-bis(4-hydroxy-3-methylphenyl)propane, 2,2-bis-(3-chloro-4-hydroxyphenyl)-propane, 2,2-bis-(3,5-dimethyl-4-hydroxyphenyl)-propane, 2,4-bis-(4-hydroxyphenyl)-2-methylbutane, 2,4-bis-(3,5-dimethyl-4-hydroxyphenyl)-2-methylbutane, 4,4-bis(4-hydroxyphenyl)heptane, bis-(3,5-dimethyl-4-hydroxyphenyl)-methane, 1,1-bis-(4-hydroxyphenyl)-cyclohexane, 1,1-bis-(3,5-dimethyl-4-hydroxyphenyl)-cyclohexane, 2,2-(3,5,3′,5′-tetrachloro-4,4′-dihydroxydiphenyl)propane, 2,2-(3,5,3′,5′-tetrabromo-4,4′-dihydroxydiphenyl)propane, (3,3′-dichloro-4,4′-dihydroxyphenyl)methane, bis-(3,5-dimethyl-4-hydroxyphenyl)-sulphon, bis-4-hydroxyphenylsulphon, bis-4-hydroxyphenylsulphide.

The carbonate precursor may be a carbonyl halogenide, a halogen formate or carbonate ester. Examples of carbonyl halogenides are carbonyl chloride and carbonyl bromide. Examples of suitable halogen formates are bis-halogen formates of divalent phenols such as hydroquinone or of glycols such as ethylene glycol. Examples of suitable carbonate esters are diphenyl carbonate, di(chlorophenyl)carbonate, di(bromophenyl)carbonate, di(alkylphenyl)carbonate, phenyltolylcarbonate and the like and mixtures thereof. Although other carbonate precursors may also be used, it is preferred to use the carbonyl halogenides and in particular carbonylchloride, also known as phosgene.

The aromatic polycarbonates in the composition according to the invention may be prepared using a catalyst, an acid acceptor and a compound for controlling the molecular mass.

Examples of catalysts are tertiary amines such as triethylamine, tripropylamine and N,N-dimethylaniline, quaternary ammonium compounds such as tetraethylammoniumbromide and quaternary phosphonium compounds such as methyltriphenylfosfoniumbromide.

Examples of organic acid acceptors are pyridine, triethylamine, dimethylaniline and so forth. Examples of inorganic acid acceptors are hydroxides, carbonates, bicarbonates and phosphates of an alkali metal or earth alkali metal.

Examples of compounds for controlling the molecular mass are monovalent phenols such as phenol, p-alkylphenols and para-bromophenol and secondary amines.

Component b)

The term “laser direct structuring additive” or “LDS additive” is known and used e.g. in e.g. EP2291290B1, US2005064711, WO2005103113 and WO2009024496. In a laser direct structuring process, a thermoplastic composition comprising a thermoplastic resin and a laser direct structuring additive is provided and the thermoplastic composition is irradiated at areas on which conductive tracks are to be formed with laser radiation. Subsequently the irradiated areas are selectively metalized to form conductive tracks. No metallization occurs on the areas that are not irradiated with laser radiation. The metallization can be done e.g. by a standard electroless plating process, such as a copper plating process.

Without wanting to be bound by any theory, it is believed that the laser direct structuring additive may be capable of being activated by laser radiation and thereby form elemental metal particles. It is believed that these metal particles act as nuclei for copper deposition in a standard electroless copper plating process and form the basis for the formation of conductive tracks. It is also possible that the radiation is not directly absorbed by the laser direct structuring additive, but is absorbed by other substances which then transfer the absorbed energy to the laser direct structuring additive and thus bring about the liberation of elemental metal.

The laser radiation may be UV light (wavelength from 100 to 400 nm), visible light (wavelength from 400 to 800 nm), or infrared light (wavelength from 800 to 25 000 nm). Other preferred forms of radiation are X-rays, gamma rays, and particle beams (electron beams, α-particle beams, and β-particle beams). The laser radiation is preferably infrared light radiation, more preferably with a wavelength of 1064 nm.

Examples of the LDS additive include copper containing spinels such as copper chromium oxide spinel, copper molybdenum oxide spinel and copper chromium manganese oxide spinel; and tin containing oxides such as tin antimony oxide, tin bismuth oxide, tin aluminum oxide and tin molybdenum oxide.

Copper chromium oxide spinel that can be used as LDS additives include the ones such as sold under commercial name Black 1G from Shepherd Color Company.

Preferred examples of LDS additives comprise antimony-doped tin oxide and having a CIELab colour value L* of at least 45, as described in WO2012/126831. Examples include Lazerflair 825, Lazerflair 820, Minatec 230 A-IR from Merck KGaA. Further examples include Stanostat CP5C from Keeling & Walker and 25-3511 PK from Ferro.

Further examples of preferred LDS additives include a mixed metal oxide comprising at least tin and a second metal selected from the group consisting of antimony, bismuth, aluminum and molybdenum, wherein the LDS additive comprises at least 40 wt % of tin and wherein the weight ratio of the second metal to tin is at least 0.02:1 as described in WO2013/076314. Examples include Stanostat CP40W and CP15G from Keeling & Walker.

The concentration of the component b) present in the composition of the present invention is preferably between 0.5 wt % and 25 wt %, more preferably between 1 and 20 wt %, even more preferably between 3 wt % and 15 wt %, and particularly preferably from 5 wt % up to 10 wt %, with respect to the weight of the total composition.

Component c)

The thermoplastic composition according to the invention comprises a methylmethacrylate butadiene styrene (MBS) based rubber having a butadiene content of at least 50 wt %.

The MBS based rubber is a graft copolymer comprising a core comprising a butadiene-sytrene copolymer and a shell comprising methyl methacrylate. The MBS based rubber is prepared through graft polymerization of a butadiene-styrene copolymer (core) with methyl methacrylate and optionally an aromatic vinyl compound, a vinyl cyanide compound and any other methacrylate ingredient (shell). For producing the MBS based rubber, any of bulk polymerization, solution polymerization, suspension polymerization, emulsification polymerization etc. may be utilized, and the system of copolymerization may be a single stage grafting or multistage grafting. From the aspect of productivity and facilitating particle size control, emulsion polymerization is preferred, and multi-step emulsion polymerization is more preferred. The polymerization method disclosed in Japanese Unexamined Patent Application Publication No. 2003-261629, for example, can be noted as this kind of multi-stage emulsion polymerization method.

The core has a glass transition temperature of generally 0 degrees centigrade or less, preferably −20 degrees centigrade or less, more preferably-30 degrees centigrade or less.

The butadiene-styrene copolymer is preferably a butadiene-styrene block copolymer obtained by the copolymerization of 75-99 mass percent of 1,3-butadene and 1-25 mass percent of styrene.

In addition, aromatic polyfunctional vinyl compounds such as divinyl benzene, divinyl toluene, and the like; unsaturated carboxylic acid esters of a polyhydric alcohol such as ethylene glycol dimethacrylate, 1,3-butane diol diacrylate, trimethylol ethane triacrylate, trimethylol propane trimethacrylate, pentaerythritol tetramethacrylate, and the like; allyl esters of unsaturated carboxylic acids such as acryl acrylate, acryl methacrylate, and the like; and di- and tri-aryl compounds such as diaryl phthalate, diaryl sebacate, triaryl triazine, and other crosslinking monomers can be used together therewith.

The content of the butadiene in the MBS based rubber of the invention is at least 50 wt %. This leads to a molded part with a conductive track having a good delamination property in combination with a high Vicat temperature and flame retardancy. A good impact strength is also obtained. The content of the butadiene in the MBS based rubber of the invention is preferably at least 55 wt %, preferably at least 60 wt %, preferably at least 65 wt %. The content of the butadiene in the MBS based rubber of the invention is preferably at most 95 wt %, preferably at most 90 wt %, preferably at most 85 wt %.

The average particle size of the MBS based rubber is preferably 70-300 nm, preferably 100-280 nm, preferably 130-260 nm, preferably 160-240 nm. This leads to a molded part with a conductive track having a good delamination property in combination with a high Vicat temperature and flame retardancy. A good impact strength is also obtained. When the average particle size is less than the above lower limit, the impact resistance of the polycarbonate resin composition of the present invention is likely to be inadequate, and if the average particle size exceeds the above upper limit, the flame resistance and fire retardant properties of the polycarbonate resin composition of the present invention are likely to decrease. An average particle size of 170-220 nm is more preferred, and 180-210 nm is even more preferred. It should be noted that the average particle size is determined from the D₅₀ of the volume-average particle size value when the graft polymer solution after the end of polymerization is measured by dynamic light scattering (DLS). For example, measurement can be carried out using a “Microtrac particle size analyzer 9230UPA” manufactured by NIKKISO Co.

The MBS based rubber preferably has a powder size D₅₀ of 160-250 μm. The powder size is herein understood as the size of the particulates of the rubber before addition to the thermoplastic composition according to the invention. Preferably, the MBS based rubber preferably has a powder size D₅₀ of 170-240 μm or 180-230 μm.

The MBS based rubber preferably has a refractive index of at most 1.55, preferably between 1.50-1.54 or 1.51-1.53.

Preferably, the MBS based rubber has a butadiene content of at least 50 wt % and an average particle size of 70-300 nm. Preferably, the MBS based rubber has a butadiene content of at least 50 wt % and a refractive index of at most 1.55. Preferably, the MBS based rubber has a butadiene content of at least 50 wt % and an average particle size of 70-300 nm and a refractive index of at most 1.55.

Examples of such MBS based rubber include “Paraloid EXL2602,” “Paraloid EXL2603” and “Paraloid EXL2655” manufactured by Rohm and Haas JAPAN K.K., “Metablen C-223A” and “Metablen E-901” manufactured by Mitsubishi Rayon Co., Ltd., “Stafiloid IM-601” manufactured by GANZ CHEMICAL CO., LTD., “Kane Ace M-511” and “Kane Ace M-600” manufactured by Kaneka Corporation.

Total of a)-d)

Preferably, the total of a)-d) is at least 75 wt % of the total composition. The total of a)-d) may be at least 80 wt %, at least 90 wt %, at least 95 wt %, at least 98 wt % or at least 99 wt % of the total composition. The total of a)-d) may be 100 wt % of the total composition.

Other Additives

The thermoplastic composition according to the invention may further comprise e) from 0 up to 25 wt % of one or more other additives, relative to the total weight of the composition. These include the customary additives such as stabilizers against thermal or thermo-oxidative degradation, stabilizers against hydrolytic degradation, stabilizers against degradation from light, in particular UV light, and/or photo-oxidative degradation, anti-drip agents such as for example PTFE, processing aids such as release agents and lubricants, colourants such as pigments and dyes. Suitable examples of such additives and their customary amounts are stated in the aforementioned Kunststoff Handbuch, 3/1. The total amount of the additives is typically 0 to 5 wt %, for example 0.5 to 3 wt %.

The additives e) may comprise further flame retardants or no further flame retardants. The additives e) may comprise chlorine and bromine flame retardants. When present, the thermoplastic composition may comprise more than 100 parts per million by weight (ppm), more than 150 ppm or more than 200 ppm, of the chlorine and bromine flame retardants, based on the total weight of the composition. The thermoplastic composition of the present invention may also be essentially free of chlorine and bromine flame retardants, i.e. comprises at most 100 ppm of of the chlorine and bromine flame retardants, based on the total weight of the composition.

Preferably, the total of a)-e) is at least 90 wt %, at least 95 wt %, at least 98 wt % or at least 99 wt % of the total composition. The total of a)-e) may be 100 wt % of the total composition.

The composition according to the invention may further comprise f) polyester. Alternatively, the composition according to the invention may comprise little or no amount of f) polyester.

Examples of suitable polyesters are polyethylene terephtalate (PET), polybutylene terephtalate (PBT), polypropylene terephtalate (PPT), polyethylene naphtanoate (PEN), polybutylene naphtanoate (PBN). Preferred polyesters are polyethylene terephtalate and polybutylene terephtalate.

The amount of f) polyester is 0-48.7 wt % with respect to the weight of the total composition, wherein the weight ratio of f) polyester to a) aromatic polycarbonate is 0:100-100:100. When present, the amount of f) polyester is to be selected such that the desired properties, in particular the combination of good flame retardancy, good Vicat temperature and good delamination resistance is obtained.

The amount of f) polyester may be selected with respect to the amount of a) aromatic polycarbonate. In some embodiments, the weight ratio of f) polyester to a) aromatic polycarbonate is 25:100-100:100, for example 25:100-60:100, 30:100-55:100 or 40:100-50:100, or 40:100-100:100, 60:100-100:100 or 80:100-100:100. In some embodiments, the polyester is polyethylene terephtalate and the weight ratio off) polyester to a) aromatic polycarbonate is 25:100-60:100. In some embodiments, the polyester is polybutylene terephtalate and the weight ratio of f) polyester to a) aromatic polycarbonate is 40:100-100:100. The relatively high amount of f) polyester is advantageous in relation to the impact strength. When the composition according to the invention does not comprise polyester, the presence of the component d) in the composition according to the invention lowers the impact strength compared to a composition not comprising component d). However, the presence of further polyester in the composition according to the invention was found to have a positive effect on the impact strength.

In some embodiments, the weight ratio of f) polyester to a) aromatic polycarbonate is 0:100-25:100, for example up to 15:100, up to 10:100 or up to 5:100. In some embodiments, the amount off) polyester is 0-15 wt %, for example 0-10 wt %, for example 0-5 wt %, for example less than 1 wt % or for example 0 wt %, with respect to the weight of the total composition. The relatively low or no amount of f) polyester is advantageous in relation to the Vicat temperature.

Preferably, the total of a)-d) and f) is at least 75 wt % of the total composition. The total of a)-d) and f) may be at least 80 wt %, at least 90 wt %, at least 95 wt %, at least 98 wt % or at least 99 wt % of the total composition. The total of a)-d) and f) may be 100 wt % of the total composition.

Preferably, the total of a)-f) is at least 90 wt %, at least 95 wt %, at least 98 wt % or at least 99 wt % of the total composition. The total of a)-f) may be 100 wt % of the total composition.

In addition to the components described above, reinforcing agents such as glass fibres can be added to the thermoplastic composition according to the present invention. It is to be understood that the reinforcing agents such as glass fibres are not included in the weight of the total composition of the thermoplastic composition according to the present invention for the calculation of the concentration of each of the components. The weight ratio of the reinforcing agents such as glass fibres to the thermoplastic composition according to the present invention may be at most e.g. 1:1 or 1:2, and at least e.g. 1:20 or 1:10. Accordingly, the present invention provides a composition comprising the thermoplastic composition according to the present invention and reinforcing agents such as glass fibres.

It is noted that the present invention also relates to a thermoplastic composition which does not or substantially does not include reinforcing agents such as glass fibres. The present invention also relates to the thermoplastic composition which includes reinforcing agents such as glass fibres at a weight ratio of the reinforcing agents such as glass fibres to the thermoplastic composition according to the present invention of at most 1:20, 1:50 or 1:100.

The components b) and optionally c), d) and other additives as described above may be introduced into the thermoplastic resin a) by means of suitable mixing devices such as single-screw or twin-screw extruders, preferably a twin-screw extruder is used. Preferably, thermoplastic resin pellets are introduced into the extruder together with at least components b) and extruded, then quenched in a water bath and then pelletized. The invention therefore further relates to a process for producing a thermoplastic composition according to the present invention by melt mixing components a), b), c), d) and other (particulate) additives and reinforcing agents.

Although the invention has been described in detail for purposes of illustration, it is understood that such detail is solely for that purpose and variations can be made therein by those skilled in the art without departing from the spirit and scope of the invention as defined in the claims.

It is further noted that the invention relates to all possible combinations of features described herein, preferred in particular are those combinations of features that are present in the claims. It will therefore be appreciated that the combinations of the features relating to the moulding step, the irradiating step and the metallizing step of the process of the invention and the features relating to the composition according to the invention are described herein. For example, the present description discloses a process for producing a circuit carrier, comprising providing the molded part comprising the thermoplastic composition according to the invention; irradiating areas of said part on which conductive tracks are to be formed with laser radiation; and subsequently metalizing the irradiated areas, wherein component d) is a phosphazene compound and the the irradiation of the molded part is performed by infrared light having a wavelength from 800 to 25 000 nm.

It is further noted that the term ‘comprising’ does not exclude the presence of other elements. However, it is also to be understood that a description on a product comprising certain components also discloses a product consisting of these components. Similarly, it is also to be understood that a description on a process comprising certain steps also discloses a process consisting of these steps.

The invention is now elucidated by way of the following examples, without however being limited thereto.

Experiments

Comparative experiments (CEx) and example compositions (Ex) were prepared from the components as given in Table 1. Additionally, additives for processing and stabilization were added. These additives include Mold Release Agent (Loxiol P861/3.5, supplied by Cognis), Heat Stabilizer (Irgafos 168, supplied by BASF), Antioxidant (Irganox 1076, supplied by BASF), PTFE (Dispersion 40, supplied by DuPont) and Mono Zinc Phosphate (Z 21-82, supplied by Budenheim).

All sample compositions were prepared according to the amounts as given in Table 2. All amounts are in weight percentage. In each of the experiments, samples were extruded on a co-rotating twin screw extruder at a temperature of 280°. The extrudate was granulated and the collected granulate was dried for 4 hours at a temperature of 120° C. and subsequentialy injection molded into plaques of 70*50*2 mm, using a machine temperature of 290° C.

The molded plaques were lasered using a LPKF MicroLine3D 160i Laser, which a hatch size of 45 μm. On each plaque 8 stripes of 3 mm width were lasered each having different laser settings in Power, Frequency and Speed as shown in Table 2. LPKF MicroLine3D 160i Laser is an infrared light having a wavelength of 1064 nm.

After laser activation the plaques were plated in MacDermid plating baths with approximately 1-2 μm Copper by MID Cu 100 strike, approximately 10-12 μm Copper by MID Cu 100 build and approximately 2-4 μm Nickel by MP Ni 200.

The plated plaques were exposed for 48 hrs in a climate chamber at 85° C. and 85% Relative Humidity.

Subsequently the plaques were cooled down to room temperature and the reduction in adhesion strength was measured according ISO 2409:2013 using a Scotch 3M 610-1PK adhesive tape with a width of 25.4 mm. Adhesion loss after temperature humidity exposure was judged by visual inspection on the amount of metal track that was removed from the plaque surface and is rated according the classification of ISO 2409:2013, where a classification of 0 means no detachment of the metal tracks and a classification of 5 means more than 65% detachment of the metal tracks from the substrate.

TABLE 1

| Material | Type | Supplier |
|---|---|---|
| Polycarbonate (PC) | LVN (ISO 1628/4) = 50 ml/g | MEP |
| MBS | Kane Ace M511 | Kaneka |
| Siloxane rubber | Kane Ace MR-02 | Kaneka |
| LDS Additive | Black 1G (CuCr₂O₄) | Shepherd Color |
| | | Company |
| Phenoxyphosphazene | Rabitle FP-110 | Fushimi |
| oligomer | | Pharmaceutical |
| | | Co., Ltd. |

TABLE 2

| | | Sample | | | | | |
|---|---|---|---|---|---|---|---|
| | Unit | CEx 1 | CEx 2 | CEx 3 | CEx 4 | CEx 5 | Ex 1 |
| Components | | | | | | | |
| PC | % | 91 | 86 | 86 | 87 | 80 | 80 |
| MBS | % | | | 5 | | | 5 |
| Siloxane rubber | % | | 5 | | | 5 | |
| LDS additive | % | 8 | 8 | 8 | 8 | 8 | 8 |
| Phosphazene | % | | | | 4 | 6 | 6 |
| Other Additives | % | 1 | 1 | 1 | 1 | 1 | 1 |
| Total | % | 100 | 100 | 100 | 100 | 100 | 100 |
| Properties | | | | | | | |
| Vicat | ° C. | 145 | 145 | 142 | 135 | 126 | 125 |
| Izod Notched Impact 23° C. | kJ/m² | 72 | 64 | 61 | 69 | 65 | 63 |
| Izod Notched Impact −20° C. | kJ/m² | 22 | 53 | 46 | 12 | 50 | 18 |
| UL at 3.2 mm | — | V-0 | V-0 | NC | V-0 | V-0 | V-0 |
| Adhesion of metal tracks after | | | | | | | |
| 48 hrs at 85° C.-85% RH | | | | | | | |
| 5 W/35 kHz/1.5 m/s | | 2 | 5 | 2 | 2 | 5 | 0 |
| 8 W/35 kHz/1.5 m/s | | 2 | 5 | 2 | 2 | 5 | 0 |
| 5 W/45 kHz/2 m/s | | 5 | 5 | 2 | 3 | 5 | 0 |
| 8 W/45 kHz/2 m/s | | 5 | 5 | 2 | 2 | 5 | 0 |
| 5 W/65 kHz/3 m/s | | 5 | 5 | 2 | 5 | 5 | 0 |
| 8 W/65 kHz/3 m/s | | 5 | 5 | 3 | 3 | 5 | 0 |
| 5 W/85 kHz/4 m/s | | 5 | 5 | 5 | 4 | 5 | 0 |
| 8 W/85 kHz/4 m/s | | 5 | 5 | 1 | 5 | 5 | 0 |

It can be seen that only the combination of MBS and phosphazene in the compositions of table 2 results in an excellent adhesion of the conductive track to the molded part.

Further experiments A-D were performed to prepare compositions from the components as given in Table 3. Additionally, additives for processing and stabilization were added. These additives include Mold Release Agent (Loxiol P861/3.5, supplied by Cognis), Heat Stabilizer (Irgafos 168, supplied by BASF), Antioxidant (Irganox 1076, supplied by BASF), PTFE (Dispersion 40, supplied by DuPont) and Mono Zinc Phosphate (Z 21-82, supplied by Budenheim).

All sample compositions were prepared according to the amounts as given in Table 4. All amounts are in weight percentage. In each of the experiments, samples were extruded on a co-rotating twin screw extruder at a temperature of 280°. The extrudate was granulated and the collected granulate was dried for 4 hours at a temperature of 120° C. and subsequently injection molded into plaques of 70*50*2 mm, using a machine temperature of 290° C.

Vicat B50 (Vicat Softening Temperature measured according to ISO 306 with a load of 50 N at a rate of 50° C./hour), Izod notched impact strength at 23° C. and −20° C. and flame retardancy (UL94 at 0.8 mm) were measured for the obtained plaques.

TABLE 3

| Material | Type | Supplier |
|---|---|---|
| Polycarbonate (PC) | LVN (ISO 1628/4) = 50 ml/g | MEP |
| PET | Ramapet N180 | Indorama |
| MBS | Kane Ace M511 | Kaneka |
| LDS Additive | Black 1G (CuCr₂O₄) | Shepherd Color |
| | | Company |
| Phenoxyphosphazene | SPB-100 | Hebron |
| oligomer | | |
| Filler 1 | Kronos 2233 (TiO2) | Kronos |
| Filler 2 | Actilox 200 HS1 (AlOOH) | Nabaltec |

TABLE 4

| | | Sample | | | |
|---|---|---|---|---|---|
| | Unit | A | B | C | D |
| Components | | | | | |
| PC | % | 54 | 52 | 52 | 50 |
| PET | % | 27 | 26 | 26 | 25 |
| MBS | % | 10 | 10 | 10 | 10 |
| LDS additive | % | 6 | 6 | 6 | 6 |
| Phosphazene | % | | 3 | 3 | 6 |
| Filler 1 | % | 2 | 2 | | |
| Filler 2 | % | | | 2 | 2 |
| Other Additives | % | 1 | 1 | 1 | 1 |
| Total | % | 100 | 100 | 100 | 100 |
| Properties | | | | | |
| MFI (280° C./1.2 kg) | dg/min | 3.6 | 6.2 | 4.9 | 6.7 |
| Vicat | ° C. | 131 | 115 | 116 | 105 |
| Izod Notched Impact 23° C. | kJ/m² | 54 | 72 | 73 | 64 |
| Izod Notched Impact −20° C. | kJ/m² | 24 | 27 | 28 | 44 |
| UL at 0.8 mm | Class | NC | HB | HB | HB |

It can be seen from experiment A that the addition of PET to a composition comprising polycarbonate, MBS and LDS additive without phosphazene leads to low flame retardancy. From experiments B-D, it can be seen that the addition of phosphazene results in an improvement in the flame retardancy although the Vicat temperature decreases.

It is notable that the impact strength was substantially increased by the addition of phosphazene. Comparing CEx 3 and Ex. 1 (Table 2), the impact strength was lowered by the addition of phosphazene. However, according to experiments A-D in which the compositions comprise PET, the impact strength was increased by the addition of phosphazene.

What is claimed is:

1. A thermoplastic composition comprising:
a) 30-97 wt % of an aromatic polycarbonate;
b) 0.5-25 wt % of a laser direct structuring additive; and
c) 2-15 wt % of a methylmethacrylate butadiene styrene based rubber having a butadiene content of at least 50 wt %;
d) 0.1-15 wt % of a conductive track adhesion agent that is one or more of an organic phosphate and a phosphazene compound, wherein a molded part of the composition provided with a conductive track made by a laser radiation and a subsequent metallization has a classification 0 as determined according to ISO2409:2013 after being subjected to conditions of 65° C. and 85% Relative Humidity for 24 hours.

2. The composition according to claim 1, wherein component d) is the phosphazene compound.

3. The composition according to claim 1, wherein component d) is a mixture of calcium hypophosphite and resorcinol tetraphenyl diphosphate.

4. The composition according to claim 1, wherein the methylmethacrylate butadiene styrene based rubber has a powder size D₅₀ of 160-250 μm.

5. The composition according to claim 1, wherein the methylmethacrylate butadiene styrene based rubber has a refractive index of at most 1.55.

6. The composition according to claim 1, wherein the molded part of the composition is capable of achieving UL94 V0 rating at a thickness of 3.2 mm (±10%).

7. The composition according to claim 1, wherein the Vicat B50, which is Vicat Softening Temperature measured according to ISO 306 with a load of 50 N at a rate of 50° C./hour, of the molded part of the composition is higher than 140° C.

8. The composition according to claim 1, wherein the Izod Notched impact strength at 23° C. measured at a sample thickness of 3.2 mm or less according to ISO 180/4A of the molded part of the composition is a value higher than 20 kJ/m².

9. The molded part comprising the thermoplastic composition according to claim 1.

10. A process for producing a circuit carrier, comprising providing the molded part according to claim 9; irradiating areas of said part on which conductive tracks are to be formed with laser radiation; and subsequently metalizing the irradiated areas.

11. The circuit carrier obtainable by the process according to claim 10.

12. An antenna comprising the circuit carrier according to claim 11.

13. A method for forming a molded part, comprising the steps of: forming a molded part from a composition comprising an organic phosphate, and/or a phosphazene compound

13. A method for forming a molded part, comprising the steps of: forming a molded part from a composition comprising an organic phosphate, and/or a phosphazene compound an aromatic polycarbonate, a methylmethacrylate butadiene styrene based rubber and a laser direct structuring additive and providing a conductive track on the molded part by a laser radiation and a subsequent metallization.

14. The method according to claim 13 wherein the molded part of the composition provided with the conductive track achieves a classification 0 as determined according to ISO2409:2013 after being subjected to conditions of 65° C. and 85% Relative Humidity for 24 hours.

15. The method according to claim 13, wherein the composition comprises
a) 30-97 wt % of an aromatic polycarbonate;
b) 0.5-25 wt % of a laser direct structuring additive; and
c) 2-15 wt % of a methylmethacrylate butadiene styrene based rubber;
d) 0.1-15 wt % of a conductive track adhesion agent that is one or more of an organic phosphate and a phosphazene compound.

16. The composition according to claim 2, wherein component d) is a phenoxyphosphazene oligomer.
